(19) United States
(12) Patent Application Publication
(10) Pub. No.: US 2005/0112838 A1
(43) Pub. Date: May 26, 2005

(54) Method for forming inductor of semiconductor device

(76) Inventors: Hyung Jun Kim, Chungcheongbuk-do (KR); Young Soo Kang, Daegu (KR)

Correspondence Address: LADAS & PARRY LLP, 224 SOUTH MICHIGAN AVENUE, SUITE 1200, CHICAGO, IL, 60604, US

(21) Appl. No.: 10/745,985

(22) Filed: Dec. 24, 2003

(30) Foreign Application Priority Data
Nov. 26, 2003 (KR) 2003-84303

(51) Int. Cl. H01L 21/20

(52) U.S. Cl. 438/381

(57) ABSTRACT

Disclosed is a method for forming an inductor of a semiconductor device. The method includes the steps of forming an inductor pattern in an insulation layer after forming the insulation layer on a lower layer pattern, forming a barrier metal layer on a surface of the insulation layer including the inductor pattern, forming a copper thin film on the barrier metal layer by a thickness enough to fill the inductor pattern with the copper thin film, planarizing the copper thin film through a planar process by using slurry providing a high polishing rate identical to or more than 10,000 Å/min, and removing the barrier metal layer from the insulation layer through the planar process using slurry capable of polishing a barrier metal. Since slurry providing the high polishing rate is used, copper is polished at a high polishing rate under a conventional polishing condition or a low polishing pressure condition.

### BACKGROUND OF THE INVENTION

1. Field of the invention

The present invention relates to a method for forming a semiconductor device, and more particularly to a method for forming an inductor of a semiconductor device, in which a copper layer can be polished at a high polishing rate by using slurry capable of polishing the copper layer at the high polishing rate under a conventional polishing condition or a low polishing pressure condition.

2. Description of the Prior Art

Hereinafter, a conventional method for forming a copper wiring of a semiconductor device will be described with reference to FIGS. 1a to 1b.

FIGS. 1a to 1b are sectional views for explaining the conventional method for forming the copper wiring of the semiconductor device.

As shown in FIG. 1a, according to the conventional method for forming the copper wiring of the semiconductor device, after sequentially depositing an etch stop layer 13 and an insulation layer 15 on a lower layer pattern 11, predetermined portions of the insulation layer 15 and the etch stop layer 13 are sequentially removed for forming an inductor pattern 17 exposing an upper surface of the lower layer pattern 11.

Then, after depositing a barrier metal layer 19 on the insulation layer 15 including the inductor pattern 17, a copper thin film 21 is deposited on the barrier wire layer 19 by a thickness enough to fill the inductor pattern 17.

As shown in FIG. 1b, a copper wiring 21a is finally formed by removing the copper thin film 21 and the barrier metal layer 19 through a CMP (Chemical Mechanical Polishing) process.

As explained above, the copper thin film, which is deposited to form the copper wiring, has a thickness identical to or less than 1 μm. In addition, the CMP process is carried out by using commercially used slurry capable of removing copper and having a polishing rate of 6,000-10,000 Å/min.

However, in order to form the wiring in an article, such as an inductor including the copper layer having a thickness above a few μm, much time is required to polish the copper layer by using conventional commercially used slurry. Therefore, the usage of consumption goods including slurry and polishing pads may increase, and thus, manufacturing cost may increase.

In addition, because the polishing process is carried out for a long time, the degree of uniformity may be lowered so that a yield rate of the semiconductor device may be decreased.

### SUMMARY OF THE INVENTION

Accordingly, the present invention has been make to solve the above-mentioned problems occurring in the prior art, and an object of the present invention is to provide a method for forming an inductor of a semiconductor device, in which a copper layer can be polished at a high polishing rate by using slurry having a high polishing rate under a conventional polishing condition or a low polishing pressure condition.

Another object of the present invention is to provide a method for forming an inductor of a semiconductor device capable of remarkably shortening a process time by rapidly removing a copper layer using slurry capable of polishing the copper layer at the high polishing rate, thereby reducing manufacturing costs.

In order to accomplish this object, there is provided a method for forming an inductor of a semiconductor □device, the method comprising the steps of: forming an inductor pattern in an insulation layer after forming the insulation layer on a lower layer pattern; forming a barrier metal layer on a surface of the insulation layer including the inductor pattern; forming a copper thin film on the barrier metal layer by a thickness enough to fill the inductor pattern with the copper thin film; planarizing the copper thin film through a planar process using slurry providing a polishing rate identical to or more than 10,000 Å/min; and removing, the barrier metal layer from the insulation layer through the planar process using slurry capable of polishing a barrier metal.

According to another aspect of the present invention, there is provided method for forming an inductor of a semiconductor □device, the method comprising the steps of: forming an inductor pattern in an insulation layer after forming the insulation layer on a lower layer pattern; forming a barrier metal layer on a surface of the insulation layer including the inductor pattern; forming a copper thin film on the barrier metal layer by a thickness enough to fill the inductor pattern with the copper thin film; planarizing the entire copper thin film and a predetermined portion of the barrier metal layer formed on the insulation layer through a planar process by using slurry having a high polishing rate identical to or more than 10,000 Å/min and capable of polishing copper; and removing a remaining barrier metal layer through the planar process by using other slurry, which is different from slurry having the high polishing rate.

### BRIEF DESCRIPTION OF THE DRAWINGS

The above objects, features and advantages of the present invention will be more apparent from the following detailed description taken in conjunction with the accompanying drawings, in which:

FIGS. 1a to 1b are sectional views for explaining a conventional method for forming a copper wiring of a semiconductor device; and

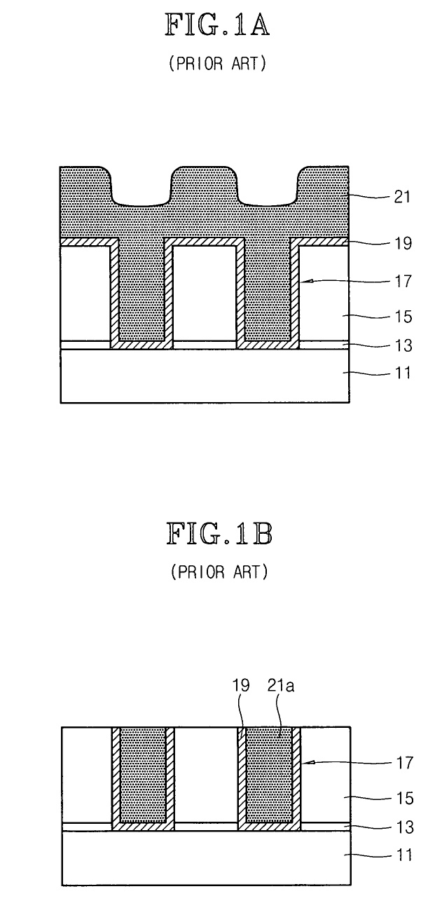

FIGS. 2a to 2c are sectional views for explaining a method for forming an inductor of a semiconductor device according to one embodiment of the present invention.

### DETAILED DESCRIPTION OF THE PREFERRED EMBODIMENTS

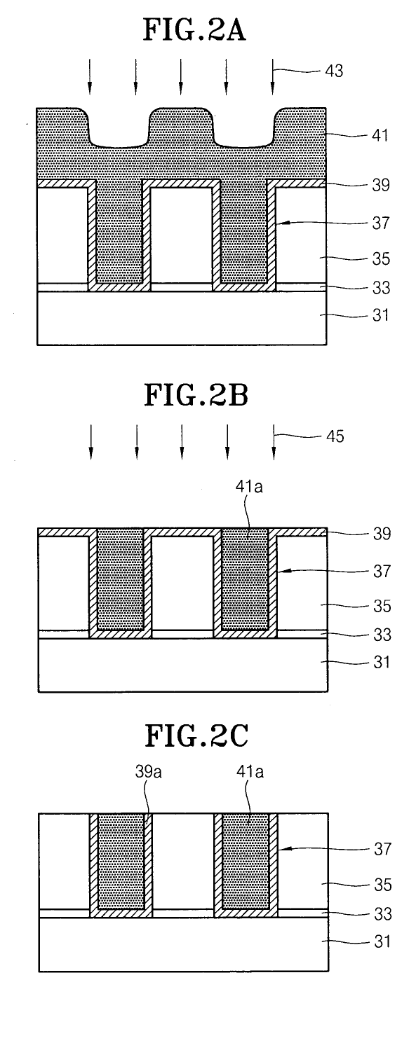

Hereinafter, a method for forming an inductor of a semiconductor device according to the present invention will be described with reference to FIGS. 2a to 2c.

FIGS. 2a to 2c are sectional views for explaining a method for forming an inductor of a semiconductor device according to one embodiment of the present invention.

According to the method for forming the inductor of the semiconductor device of the present invention, as shown in FIG. 2a, after sequentially depositing an etch stop layer 33 and an insulation layer 35 on a lower layer pattern 31, the insulation layer 35 and the etch stop layer 33 are sequentially removed, thereby forming an inductor pattern 37 exposing an upper surface of the lower layer pattern 31. At this time, the inductor pattern 37 can be formed through a damascene process.

Layer 39 on the insulation layer 35 including the inductor pattern 37, a copper thin film 41 is deposited on the barrier metal layer 39 by a thickness enough to fill the inductor pattern 37 with the copper thin film 41.

Thereafter, as shown in FIG. 2b, the copper thin film 41 is selectively removed by performing a primary CMP process 43 using polycarboxylate-based slurry having a high polishing rate or another slurry capable of removing copper. At this time, the polishing speed of slurry must be identical to or more than 10,000 Å/min, under polishing pressure about 3 psi.

Next, as shown in FIG. 2c, the barrier metal layer 39 is removed through a secondary CMP process 45 by using slurry capable of removing a barrier metal, thereby forming a copper inductor pattern 41a.

Meanwhile, although it is not illustrated in figures, according to a first embodiment of the present invention, only a predetermined part of the deposited copper thin film is removed by using slurry capable of polishing the deposited copper thin film at the high polishing rate, which is described with reference to FIG. 2a.

Then, after removing the remaining copper thin film, the barrier metal is removed by changing the kind of slurry, that is, by using another slurry.

The reason for using slurry providing a high polishing rate and different slurry to remove the copper thin film is as follows. Firstly, slurry having the high polishing rate is utilized to remove a step difference and to remove most of the copper thin film. In addition, different slurry used until the barrier metal is exposed has superior dishing and erosion characteristics as compared with those of slurry having the high polishing rate, and is utilized to remarkably reduce a step difference when the polishing process has been carried out.

Meanwhile, according to a second embodiment of the present invention, not only the copper thin film, but also the barrier metal can be removed by utilizing slurry having the high polishing rate, which is described with reference to FIG. 2a. That is, the metal between the copper wirings is entirely removed without using slurry capable of removing the barrier metal.

Next, after removing the barrier metal, a polishing process is additionally carried out in order to reduce the step difference by utilizing slurry for polishing an oxide layer.

Meanwhile, according to a third embodiment of the present invention, after removing the copper thin film and a predetermined part of the barrier metal by utilizing slurry having the high polishing rate, which is described with reference to FIG. 2a, the remaining barrier metal is entirely removed by utilizing slurry capable of polishing the barrier metal.

As explained above, according to the method for forming the inductor of the semiconductor device of the present invention, it is possible to polish a copper thin film at a high polishing rate under a conventional polishing condition or a lower polishing pressure condition by remarkably increasing a polishing rate of slurry.

Also, a thick copper layer having a thickness identical to or more than 3 μm can be polished in a short time by using polycarboxylate based slurry under a conventional polishing condition, that is, at polishing pressure about 3 psi with a polishing rate identical to or more than 18,000 Å/min. Conventionally, a polishing time of about 2 minutes is required in order to remove the copper layer having a thickness identical to or less than 1 μm in a copper wiring process. If the present invention is used for polishing the copper layer having a thickness identical to or less than 1 μm, a polishing process time can be reduced to below 1 minute.

Therefore, according to the present invention, a high polishing speed can be achieved by utilizing slurry having a high polishing rate and capable of removing copper, so manufacturing cost and manufacturing time can be reduced.

Although preferred embodiments of the present invention have been described for illustrative purposes, those skilled in the art will appreciate that various modifications, additions and substitutions are possible, without departing from the scope and spirit of the invention as disclosed in the accompanying claims.

1. A method for forming an inductor of a semiconductor □device, the method comprising the steps of:
i) forming an inductor pattern in an insulation layer after forming the insulation layer on a lower layer pattern;
ii) forming a barrier metal layer on a surface of the insulation layer including the inductor pattern;
iii) forming a copper thin film on the barrier metal layer by a thickness enough to fill the inductor pattern with the copper thin film;
iv) planarizing the copper thin film through a planar process by using slurry providing a high polishing rate identical to or more than 10,000 Å/min; and
v) removing the barrier metal layer from the insulation layer through the planar process using slurry capable of polishing a barrier metal.

2. The method according to claim 1, wherein step iv) includes the substeps of:
a) planarizing the copper thin film by a predetermined thickness through the planar process using slurry providing a high polishing rate; and
b) exposing the barrier metal layer below the copper thin film by carrying out the planar process using slurry having a low polishing rate.

3. The method according to claim 1, wherein slurry having the high polishing rate includes polycarboxylate based slurry.

4. A method for forming an inductor of a semiconductor □device, the method comprising the steps of:
i) forming an inductor pattern in an insulation layer after forming the insulation layer on a lower layer pattern;
ii) forming a barrier metal layer on a surface of the insulation layer including the inductor pattern;
iii) forming a copper thin film on the barrier metal layer by a thickness enough to fill the inductor pattern with the copper thin film;
iv) planarizing the entire copper thin film and a predetermined portion of the barrier metal layer formed on the insulation layer through a planar process by using slurry providing a high polishing rate identical to or more than 10,000 Å/min and capable of polishing copper; and
v) removing a remaining barrier metal layer through the planar process by using other slurry, which is different from slurry having the high polishing rate.

5. The method according to claim 4, wherein, other slurry includes slurry capable of polishing the insulation layer or slurry capable of polishing the barrier metal.

6. The method according to claim 4, wherein slurry having the high polishing rate and capable of polishing copper includes polycarboxylate-based slurry.
